(19) United States
(12) Patent Application Publication
(10) Pub. No.: US 2007/0161213 A1
(43) Pub. Date: Jul. 12, 2007

(54) Semiconductor device and method of manufacturing the same

(76) Inventors: Hidefumi Hiura, Tokyo (JP); Tetsuya Tada, Ibaraki (JP); Toshihiko Kanayama, Ibaraki (JP)

Correspondence Address: YOUNG & THOMPSON, 745 SOUTH 23RD STREET, 2ND FLOOR, ARLINGTON, VA, 22202, US

(21) Appl. No.: 11/589,188

(22) Filed: Oct. 30, 2006

(30) Foreign Application Priority Data
Oct. 31, 2005 (JP) 2005-315627

(51) Int. Cl. H01L 21/20; H01L 21/36

(52) U.S. Cl. 438/478

(57) ABSTRACT

A self-aligned/self-limited processing is carried out on a nanowire material typified by a carbon nanotube or on the vicinity of the nanowire material alone in the following manner. External energy is applied to the nanowire material. Joule heat, light, or a thermoelectron is thereby locally formed and acts as minute energy. The minute energy causes a chemical reaction of an externally added raw material and causes the conversion of a property of the nanowire material.

This application claims priority to prior Japanese patent application JP 2005-315627, the disclosure of which is incorporated herein by reference.

### BACKGROUND OF THE INVENTION

1. Field of the Invention

The present invention relates to semiconductor devices and methods of manufacturing the same. More specifically, it relates to semiconductor devices constitutionally containing semiconductor materials having a nanowire structure, typified by carbon nanotubes. It also relates to methods of manufacturing the semiconductor devices.

2. Description of the Related Art

Following advancing information communication technologies, demands have been made on semiconductor devices that can operate at high speed and consume less electric power, and on techniques for manufacturing such semiconductor devices. Recent semiconductor devices basically include metal oxide semiconductor (MOS) elements using silicon as a semiconductor material. These MOS elements have been manufactured by a top-down micromachining technique using lithography and etching. The lower limit of the production scale according to this technique, however, is about several tens of nanometers. Expected possible solutions to achieve a further smaller scale are bottom-up or built-up techniques in which a device is built up at an atomic level. An early-stage candidate for the bottom-up technologies is a process of carrying out the steps one by one using a local probe typified by scanning tunnel microscope. This process, however, has not become commercially practical, because it achieves only a low throughput. More suitable candidates for commercial production are techniques of forming a structure using self-organization or self-assemblage of atoms or molecules.

Conventional bottom-up micromachining techniques using self-organization may be found, for example, in the following documents. Japanese Unexamined Patent Application Publication No. 2004-142097 discloses a method, in which a substrate is subjected to surface treatment, a pattern is formed on the treated substrate by photolithography, and chemically treated carbon nanotubes are stacked on the pattern in a self-organization manner. Japanese Unexamined Patent Application Publication No. 2005-210063 discloses a technique of manufacturing a field-effect transistor by arranging a line of self-organized nanoparticles as a channel between source/drain electrodes. Japanese Unexamined Patent Application Publication No. 2005-243748 mentions that a self-organized multilayer film is formed between source/drain electrodes by using a metal thiolate, and that the resulting self-organized multilayer film serves as a channel.

Silicon is a representative semiconductor material but will reach its limitations as a material soon. The semiconductor devices become finer and finer as mentioned above. Accordingly, the solid-solution of dopants reaches its ceiling, and heat is generated to elevate the temperature higher than the melting point of the semiconductor upon operation in such fine semiconductor devices. Nanowires are self-organized semiconductor materials and receive attention as candidates for overcoming the limitations of silicon. Nanowire semiconductor materials include carbon nanotubes containing carbon as a constitutional elements. They also include nanowires containing semiconductor elements such as silicon (Si), gallium nitride (GaN), aluminum nitride (AlN), boron nitride (BN), and boron carbonitride (BCN).

Carbon nanotubes each comprise a cylindrical roll of a two-dimensional graphite sheet including carbon six-membered rings. Thus, they have a pseudo-one-dimensional structure. They are minute crystals and have a very large aspect ratio with a diameter on the order of nanometers and a length on the order of micrometers to millimeters. The carbon nanotubes are typical semiconductor materials having a nanostructure, have a drift mobility of several thousands to several tens of thousands of square centimeters per volt per second, as high as ten times or more that of silicon. The band gaps of carbon nanotubes may be structurally controlled by adjusting their diameter and helicity. Accordingly, they are highly valued as semiconductor materials to be a replacement for silicon in semiconductor devices.

Semiconductor devices using carbon nanotubes include field-effect transistors using carbon nanotubes as channels. These field-effect transistors are manufactured by a top-down micromachining technique using regular lithography and etching, as described in Japanese Unexamined Patent Application Publications No. 2003-109974, No. 2004-103802, and No. 2005-197736. Certain semiconductor devices use nanowire materials other than carbon nanotubes. They include field-effect transistors using silicon nanowires as channels disclosed in Nature, 420, 57-61 (2002), and Nature, 434, 1085 (2005). These field-effect transistors include a coaxial cylindrical hetero-structure as a component. The hetero-structure includes a silicon nanowire as a core, and a germanium (Ge) layer or silicon oxide (SiO₂) layer surrounding the silicon nanowire.

Current bottom-up micromachining techniques, however, are still susceptible to improvements in industrial applications. This is because these techniques are difficult to “constitute a desired structure in a desired place”, and techniques of “constituting a desired structure in a desired place” have not been provided yet. Under these circumstances, the lithography and etching techniques are used so as to “constitute a desired structure in a desired place” using the bottom-up technique. In other words, relatively macro-scaled top-down micromachining techniques are used to “constitute a desired structure in a desired place” using a relatively micro-scaled machining technique. These manufacturing techniques confuse natural order of things. For example, patterning is carried out by photolithography so as to carry out self-organization of a carbon nanotube according to the technique disclosed in above-mentioned Japanese Unexamined Patent Application Publication No. 2004-142097. The technique may not be said as a bottom-up micromachining process. It does not provide a semiconductor device operating at high speed and consuming less electric power. In addition, it does not establish a technique of manufacturing the semiconductor device.

The above-mentioned techniques also include problems from the viewpoint of materials. Specifically, remarkably high contact resistances between a channel and an electrode are shown in the field-effect transistors disclosed in Japanese Unexamined Patent Application Publications No. 2005-210063 and No. 2005-243748. This is because these techniques use an organic molecule and a line of nanoparticles each combining through metal ions as channels, respectively. This is so-called the “electrode problem (contact problem)” unique to organic molecules and nanoparticles. These techniques do not theoretically satisfy requirements on on-state current in next-generation transistors, as long as they use the above-mentioned materials as channels. In addition, these materials including organic molecules or nanoparticles have a more serious problem. The resulting channels have a very low mobility of about 10⁻⁶ to about 10⁻² square centimeters per volt per second. This is because they use hopping conduction between molecules or particles. Consequently, the resulting devices are impossible to operate at high speed, and the higher-performance of semiconductor devices may not be achieved,

Nanowire materials are preferably used in the next-generation semiconductor devices, in consideration of the limitations of silicon as a material. Of such nanowire materials, carbon nanotubes have excellent electronic properties, chemical stability, and mechanical strength (toughness) and can be said as the best. However, semiconductor devices having smaller dimensions may not be achieved by the conventional processing techniques using lithography and etching, even if such good materials are used. For example, carbon nanotubes are used as channels in the field-effect transistors according to the techniques disclosed in Japanese Unexamined Patent Application Publications No. 2003-109974, No. 2004-103802, and No. 2005-197736. These techniques are disadvantageous in the methods of manufacturing the transistors. Namely, the transistors are manufactured by conventional semiconductor processes using conventional semiconductor manufacturing apparatuses. The advantages of carbon nanotubes as a material are not fully enjoyed, and the next-generation semiconductor devices having smaller dimensions are not provided, as long as the top-down micromachining techniques are used.

Silicon nanowires are used in the field-effect transistors according to the techniques in Nature, 420, 57-61 (2002), and Nature, 434, 1085 (2005). Such silicon nanowires are the next best choice as the material, as is described above. According to these techniques, a silicon nanowire is used as a core, and self-organized growth is carried out to form a coaxial hetero nanostructure on the order of 50 to 100 nanometers around the core, although these techniques are macro techniques. The growth of coaxial hetero nanowires according to these techniques, however, is not a so-called “in situ growth”. According to the techniques, a macro-scale amount of the material is subjected to bulk growth, the resulting grown material is dispersed in a liquid, and the dispersion is allowed to flow in a passage arranged on a substrate to thereby align the material on the substrate.

In short, the followings are the disadvantages of the techniques in Nature, 420, 57-61 (2002), and Nature, 434, 1085 (2005). The techniques use conventional lithography and etching techniques for forming the passage. In addition, the resulting coaxial hetero nanostructures have a large diameter of 50 to 100 nanometers, which is equal to or larger than the channel widths of silicon MOS transistors manufactured by the conventional top-down micromachining techniques. Furthermore, the nanowire hetero-structure is not formed in situ in a self-alignment manner. Accordingly, semiconductor devices having smaller dimensions are not provided by the techniques having these disadvantages. The techniques are insufficient as manufacturing techniques in industrial applications.

### SUMMARY OF THE INVENTION

Accordingly, an object of the present invention is to provide a semiconductor device that solves the problems in scale and material of semiconductor devices and will provide semiconductor devices satisfying the requirements in the next-generation semiconductors. Another object of the present invention is to provide a method of manufacturing the semiconductor device.

Specifically, the present invention provides a method of manufacturing a semiconductor device, including the steps of applying external energy to a nanowire material to cause minute energy locally, externally feeding a raw material, and carrying out a chemical reaction or solid phase growth of the raw material using the minute energy to thereby carry out a self-aligned processing of the nanowire material or the vicinity thereof alone.

The nanowire material is preferably a carbon nanotube.

The external energy is preferably electric power or an electromagnetic wave. The electromagnetic wave may be, for example, a microwave or an infrared ray.

The method preferably further includes the steps of arranging the nanowire material at plural positions of a substrate, and applying an electromagnetic wave to thereby heat the nanowire material alone selectively and locally, which electromagnetic wave is such as not to be absorbed by the substrate. The minute energy may be, for example, Joule heat, light, or a thermoelectron.

The present invention further provides a method of manufacturing a semiconductor device, including the steps of applying external energy to a nanowire material to cause minute energy locally, and carrying out the local conversion of a property of the nanowire material or a property of a material arranged in the vicinity of the nanowire material using the minute energy.

The nanowire material is preferably a carbon nanotube.

The external energy is preferably electric power or an electromagnetic wave. The electromagnetic wave may be, for example, a microwave or an infrared ray.

The method preferably further includes the steps of arranging the nanowire material at plural positions of a substrate, and applying an electromagnetic wave to thereby heat the nanowire material alone selectively and locally, which electromagnetic wave is such as not to be absorbed by the substrate. The minute energy may be, for example, Joule heat, light, or a thermoelectron.

When the nanowire material includes a defect, the defect is preferably removed by annealing the nanowire material by the action of the Joule heat.

According to embodiments of the present invention, the following semiconductor devices and methods for producing the same are obtained. One of the semiconductor devices includes, as a component, a semiconductor material having a nanowire structure typified by a carbon nanotube.

Another one of the semiconductor devices includes nanowires having respectively converted properties.

Another one of the semiconductor devices a nanowire doped with a lattice-substitutional hetero element.

Yet another one of the semiconductor devices has a composite structure including a self-aligned film formed by self-heating of a nanowire.

Still another one of the semiconductor devices has a nanowire structure formed using a nanowire as a template.

In addition, the present invention provides a system of improving the performance of a semiconductor device having a nanowire.

These advantages are realized by the methods of manufacturing a semiconductor device according to the present invention. In one of the methods, the vicinity of a nanowire material alone is processed in a self-alignment manner by using Joule heat, light, or a thermoelectron as a minute energy source for causing a chemical reaction or solid phase growth of a raw material externally added. The Joule heat, light, or a thermoelectron herein occurs as a result of application of external energy. In another of the methods, a property of a nanowire material or a material arranged in the vicinity of the nanowire material is locally converted by using energy applied to the nanowire material and a raw material externally added according to necessity.

### BRIEF DESCRIPTION OF THE DRAWINGS

FIGS. 1A and 1B show the first step of a manufacturing method as an embodiment of the present invention, in which an electromagnetic wave is used;

FIGS. 2A and 2B show the first step of a manufacturing method as an embodiment of the present invention, in which electric power is used;

FIG. 3 shows the processing and conversion of properties, respectively, of a nanowire in the second step of the manufacturing method;

FIG. 4 shows a coaxial cylindrical nanowire field-effect transistor manufactured by the method according to the present invention;

FIG. 5 is a diagram showing a measuring system of the temperature, light emission, and thermoelectron emission, and of determination of electric properties;

FIGS. 6A, 6B, 6C, 6D, 6E, and 6F show a method of manufacturing a field-effect transistor as First Embodiment of the present invention, and the resulting field-effect transistor;

FIGS. 7A, 7B, 7C, and 7D show a method of manufacturing a logical circuit (ring oscillation circuit) according to Second Embodiment of the present invention, and the resulting logical circuit;

FIG. 8 shows the drain current-gate voltage characteristic of a carbon nanotube field-effect transistor, in which the conduction system is changed from p-type conduction to ambipolar conduction;

FIG. 9 is a diagram showing the change in drain current with time of a carbon nanotube field-effect transistor and demonstrates that the carbon nanotube is capable of interconnecting between a metal form and a semiconductor form; and

FIG. 10 shows the drain current-drain voltage characteristic of a carbon nanotube field-effect transistor and demonstrates that the properties of the carbon nanotube field-effect transistor are improved.

### DESCRIPTION OF THE PREFERRED EMBODIMENTS

Hereinbelow, description will be made of embodiments of the present invention with reference to the drawings.

A method of manufacturing a semiconductor device according to an embodiment of the present invention includes the steps of applying external energy to a nanowire material to cause minute energy locally, externally feeding a raw material, and carrying out a chemical reaction or solid phase growth of the raw material using the minute energy to thereby carry out a self-aligned/self-limited processing of the nanowire material or the vicinity thereof alone. One of features of the method is that the energy application causes selective and respective conversion in properties or micromachining of a nanoregion of the nanowire material itself or a nanoregion of the very vicinity of the nanowire material.

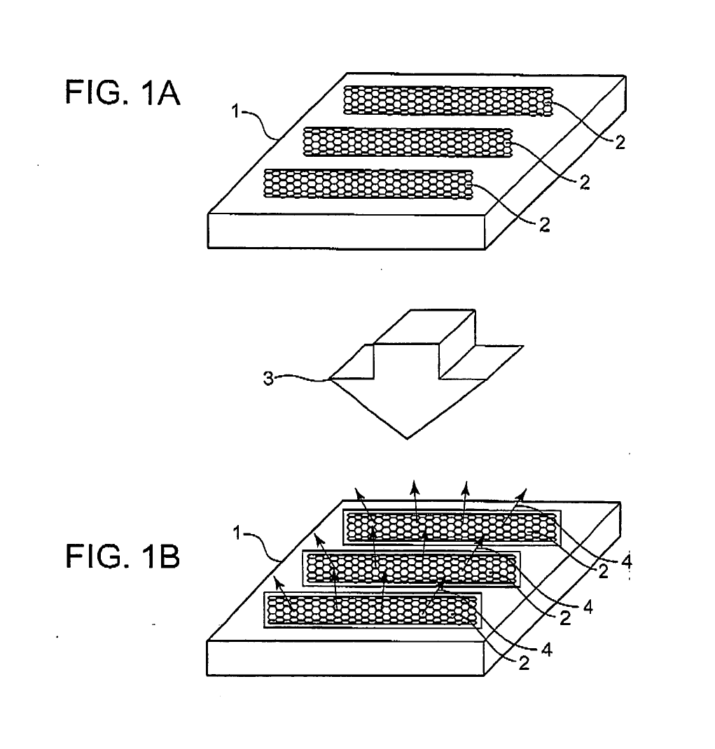

Energy is applied in the first step of the manufacturing method according to the present invention. The energy application is carried out, for example, by a process shown in FIG. 1B. In this process, an electromagnetic wave 3 is applied to a nanowire material 2, which electromagnetic wave 3 can be absorbed by the nanowire material 2. According to this process, the nanowire material 2 is basically heated by exciting the phonon of the nanowire material 2 by the action typically of a microwave or an infrared ray. The nanowire material 2 may be heated by exciting an electron of the nanowire material 2 by the action of a radiation corresponding to the band gap energy of the nanowire material 2. Such radiations include, for example, infrared rays, visible radiations, and ultraviolet rays. The excitation or heating may also be carried out using electromagnetic waves corresponding to respective energy among all the energy levels of the nanowire material 2. Namely, all the electromagnetic waves capable of being absorbed by the nanowire material 2 can be used. The nanowire material 2 can be selectively and locally heated by selecting an electromagnetic wave which a substrate 1 does not absorb. This process of applying an electromagnetic wave is suitable for heating specific regions of a semiconductor device including semiconductor elements in one step.

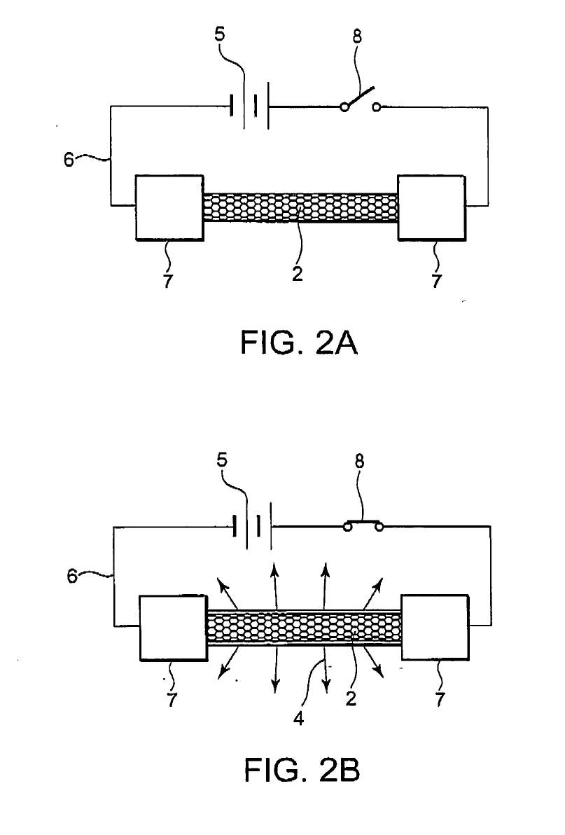

Another process for the energy application is the process shown in FIGS. 2A and 2B, in which electric power is supplied as the external energy to the nanowire material. In this process, the nanowire material 2 is connected to a power supply 5 through electrodes 7 and interconnections 6. By turning a switch 8 ON, the power supply 5 supplies electric power to the nanowire material 2. The electric power may be supplied in a direct current system or an alternating current system. A pulsed current is preferably supplied when the electric power is supplied in a short time or when heating and cooling procedures are repeated. In this process, the nanowire material 2 alone is heated from a temperature equal to or higher than room temperature to such a temperature that the nanowire material 2 melts or sublimates. The degree of heating varies depending on the electric power supplied from the power supply 5. A carbon nanotube, for example, can be heated up to about 2500 K. This process of applying electric power is suitable for selectively and respectively heating individual semiconductor elements. Minute energy 4 can be locally emitted from the nanowire material 2 by applying energy according to either of the process of applying an electromagnetic wave or the process of applying electric power, as illustrated in FIGS. 1B and 2B, respectively. The minute energy 4 may be, for example, any of Joule heat, light, and a thermoelectron.

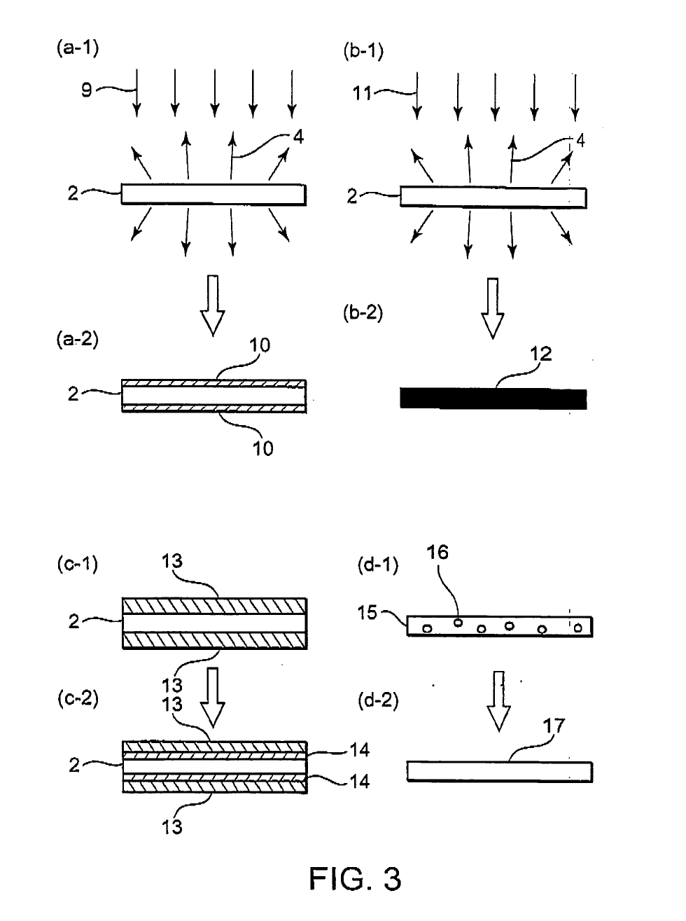

FIG. 3 shows the second step of the method according to the present invention. These figures schematically illustrate the principles of the chemical reaction and solid phase growth of a raw material externally supplied. They also illustrate the principle of converting properties of the nanowire material itself.

With reference to FIG. 3(a-1), a raw material 9 is fed to the surface of the nanowire material 2 so as to form a chemically modified layer or solid layer 10. The minute energy 4 herein is the Joule heat, light or thermoelectron emitted from the nanowire material 2. This causes a chemical reaction of the raw material 9, such as a heat reaction, thermoelectron reaction, or photoreaction, to thereby form a reaction intermediate. Next, the reaction intermediate undergoes a further chemical reaction with the surface of the nanowire material 2. Alternatively, the reaction intermediate undergoes crystallization or amorphization on the surface of the nanowire material 2 to thereby induce solid phase growth. In this stage, the very vicinity of the nanowire is selectively processed, and the reaction or growth terminates when the nanowire material 2 is covered with a very thin layer.

In other words, the former phenomenon demonstrates that the processing is a self-aligned process, and the latter demonstrates that the processing is a self-limited process. The “self-aligned process” used herein refers to a fabrication process including plural steps, in which the delimitation (demarcation) of a region in a certain step is carried out using a demarcated pattern of the region formed in a precedent step without requiring a masking registration precision. The “self-limited process” refers to a fabrication process, in which a chemical reaction or crystal growth automatically terminates. The process in FIG. 3(a-1) is a self-aligned and self-limited process. This is because the intensity of minute energy 4 diminishes proportional to the square of the distance from the nanowire material 2. The resulting nanowire has a processed surface such as a chemically modified surface or a surface covered with a layer (FIG. 3(a-2)).

In the process shown in FIG. 3(b-1), a raw material 11 is eternally fed and chemically reacts with a nanowire material 2 directly. As a result, another nanowire 12 is newly formed (FIG. 3(b-2)). The nanowire 12 has a chemical composition different from that of the original nanowire material 2. In this process, the nanowire 12 is formed by allowing the nanowire material 2 to take in part of the raw material 11 or by allowing part of the compositional elements of the nanowire material 2 to escape therefrom. In the former case, for example, a carbon nanotube may take in a metal element to form a carbide. Alternatively, a silicon nanowire may be doped with a dopant element. In the latter case, a nanowire including multiple elements may release part or all of at least one constitutional element. The nanowire including multiple elements can be for example, GaN, AlN, BN, and BCN nanowires. The process shown in FIG. 3(b-1) is useful for manufacturing a novel nanowire departing from a known nanowire according to the present invention.

FIG. 3(c-1) shows another process using a nanowire material 2 covered with a solid layer 13. In this process, energy is applied to the nanowire material 2. This causes conversion of properties of regions of the solid layer in the vicinity of the nanowire material 2 alone. Thus, another solid layer 14 is formed (FIG. 3(c-2)). This process enables the nanowire structure to have a new function.

FIG. 3(d-1) shows yet another process using a nanowire 15 including defects 16. In this process, the nanowire 15 is annealed by the action of Joule heat. This removes the defects 16 therefrom. The resulting nanowire 17 does not include defects (FIG. 3(d-2)). This is an example of the conversions of properties of nanowires. The conversions of properties of nanowires include the conversion of crystal structure, and the conversion of crystal size. For example, a semiconductor nanotube can be fabricated from a metal nano tube, or vice versa, by converting or altering the diameter or helicity of the carbon nanotube.

A significant feature of the fabrication method according to an embodiment of the present invention is that the method includes any of the self-aligned and self-limited processes. These processes are very preferable in micromachining techniques. This feature realizes micromachining and property conversion with precise control ultimately in the nanometer-scale.

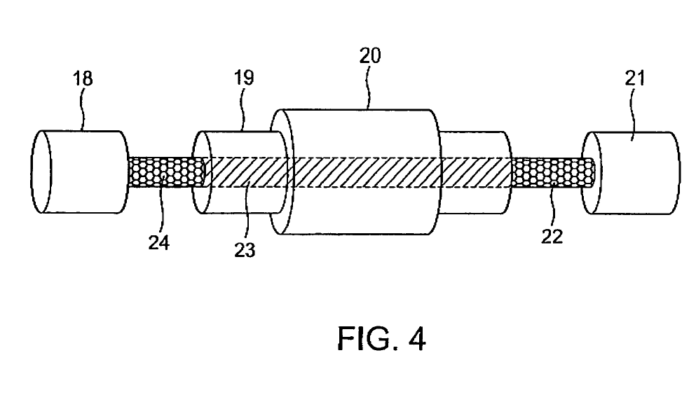

A semiconductor device according to an embodiment of the present invention includes the nanowire material 2, typified by a carbon nanotube. The semiconductor device is fabricated by the above-mentioned method. FIG. 4 illustrates a single coaxial concentric field-effect transistor as an example of the semiconductor device. The field-effect transistor comprises a channel 23, a source electrode 24, a source-electrode leading 18, a drain electrode 22, a drain-electrode leading 21, an insulating layer 19, and a gate electrode 20. The channel 23 comprises a semiconductor nanowire. The source electrode 24 is connected to a leading edge of the channel 23 and comprises a metallized nanowire. The source-electrode leading 18 is connected to the source electrode 24. The drain electrode 22 comprises a metallized nanowire and is connected to the end edge (terminal) of the channel 23. The drain-electrode leading 21 is connected to the drain electrode 22. The insulating layer 19 is arranged coaxially cylindrically around the channel 23. The gate electrode 20 is arranged coaxially cylindrically around the channel 23 with the interposition of the insulating layer 19.

Plural plies of the field-effect transistors may constitute a logical circuit. The semiconductor devices according to an embodiment of the present invention include not only field-effect transistors but also semiconductor devices including, in a specific region, a semiconductor p-type region or n-type region, or an interconnection having metallic conductivity. Each of these elements is manufactured by the above-mentioned method.

To carry out the method according to the present invention, information may be determined on how the nanowire is heated (how high the temperature is elevated) by the application of external energy, and how light and a thermoelectron is emitted as a result of heating. The followings are processes for determining the temperature, the light emission, and the properties of the thermoelectron.

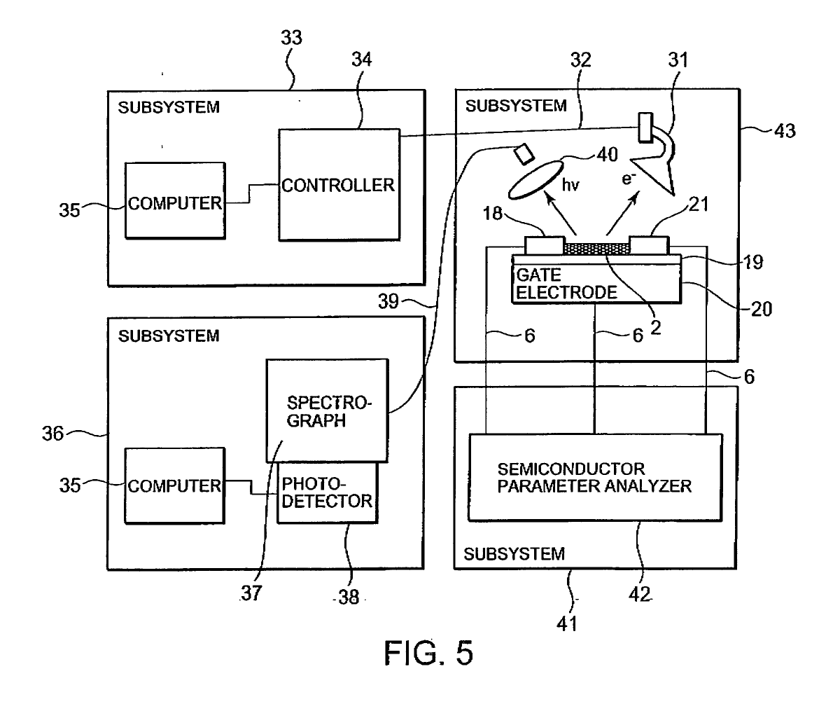

FIG. 5 is a schematic diagram showing a measuring system of the temperature, light emission, and thermoelectron emission, and of determination of electric properties. In this system, for example, electric power is supplied as the external energy to the nanowire in the first step of the manufacturing method according to the present invention.

The system illustrated in FIG. 5 comprises four subsystems 43, 41, 36, and 33. The subsystem 43 is a vacuum subsystem and serves to arrange a nanowire sample. In this system, a nanowire material 2 acts as a channel and constitutes a field-effect transistor together with a source-electrode leading 18, a drain-electrode leading 21, a gate electrode 20, and a gate insulating layer 19. The subsystems 36, 33, and 41 are a subsystem for determining the temperature and light emission, a subsystem for measuring the thermoelectrons, and a subsystem for determining electric properties, respectively. The subsystem 41 includes a semiconductor parameter analyzer 42 for determining electric properties. This is configured to determine electric properties and to act as a power supply for supplying electric energy to apply the external energy.

The temperature and light emission are determined by the subsystem 36 in FIG. 5, as is described above. The temperature may be basically determining in the following manner. The black-body radiation of the nanowire is gathered using a lens 40, is introduced via an optical fiber 39 to a spectrograph 37, and is detected by a photodetector 38. The color temperature is then determined by calculation according to the Plank radiation formula and/or the Wien's displacement low. When a carbon nanotube, for example, is used as the nanowire, the temperature may be controlled from room temperature to 2500 K according to the intensity or magnification of the external energy. The photodetector 38 is connected to a computer 35. The computer 35 serves to control the system and to process data.

The thermoelectron emission is determined by a channeltron detector 31 using the subsystem 33 in FIG. 5. Among nanowires, carbon nanotubes emit thermoelectrons satisfactorily. The subsystem 33 for determining thermoelectrons comprises a controller 34 and a computer 35. The controller 34 serves to control the channeltron detector. The computer 35 serves to control the system and to process data. The subsystem 41 in FIG. 5 is configured to determine the drain current-drain voltage characteristic and the drain current-gate voltage characteristic as the electric properties of the nanowire.

The system in FIG. 5 realizes in situ and concurrent determination of the temperature, light emission, thermoelectron emission, and electric properties of the nanowire. This is one of advantages of the system. In addition, when the system further includes a raw-material feeder in the vacuum subsystem, the system realizes monitoring of changes in properties, such as electric properties, of the nanowire before and after processing. Thus, precise control may be achieved in the steps in the manufacturing method according to the present invention. This may provide high-performance nanowire semiconductor devices. The specific embodiment shown in FIG. 5 uses the subsystem 43. A vacuum system is, however, not essential in practical fabrication. The method may be carried out in a controlled atmosphere of an inert gas such as argon gas (Ar) or nitrogen gas (N₂). When oxidation is trivial in the method, the method may also be carried out in the air.

The present invention will be illustrated in further detail with reference to several specific embodiments below and to the attached drawings.

### First Embodiment

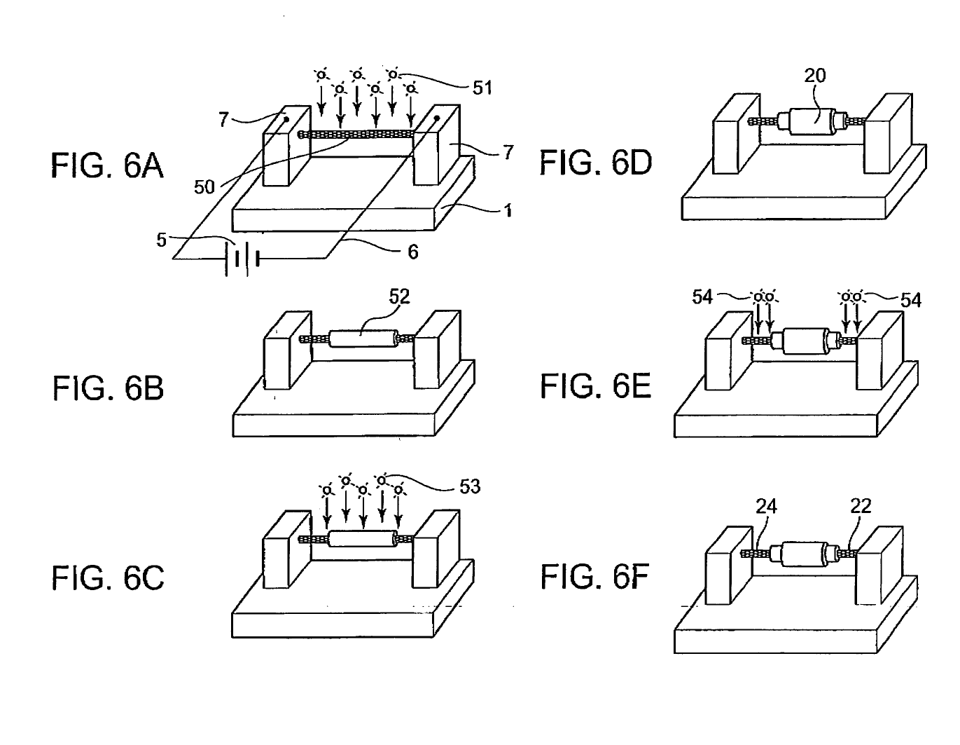

FIGS. 6A, 6B, 6C, 6D, 6E, and 6F show a method of manufacturing a field-effect transistor according to First Embodiment. These figures also show the resulting field-effect transistor.

Initially, a single-layer carbon nanotube 50 was placed in a vacuum system. Electric power was supplied to the carbon nanotube 50 from a power supply 5 through an interconnection 6 (FIG. 6A). Consequently, the carbon nanotube 50 was self-heated by the action of Joule heat according to the supplied power. It emitted heat, light, and thermoelectrons to a minute region in the vicinity of the carbon nanotube 50. Next, a raw material 51 including oxygen (O₂) and silane (SiH₄) was supplied into the vacuum system so as to form a silicon oxide layer 52 as a gate insulating layer. The heat, light, and thermoelectrons formed as a result of self-heating acted as an energy source. They caused the thermal decomposition of the raw material 51. They also caused the solid phase growth of decomposed products. Thus, a coaxial cylindrical SiO₂ gate insulating layer 52 was formed so as to cover the carbon nanotube 50 (FIG. 6B).

The SiO₂ layer was formed only in a center part of the carbon nanotube 50. This is because the electrodes 7 acted as heat sinks, and the carbon nanotube 50 had a relatively low temperature in the vicinities of the electrodes and a relatively high temperature in a center part thereof. When the gate insulating layer 52 comprises an insulator having a high dielectric constant (high-κ), the raw material may be a precursor containing O₂ in combination with a corresponding component. When the high-κ insulator is, for example, aluminum oxide (Al₂O₃), titanium dioxide (TiO₂), zirconium dioxide (ZrO₂), or hafnium dioxide (HfO₂), the corresponding component is Al, Ti, Zr, or Hf, respectively. When the insulator is, for example, HfO₂, the precursor raw material may include, for example, hafnium tetrachloride (HfCl₄) hafnium (Hf[OC(CH₃)₃]₄). When the insulator is silicon nitride (Si₃N₄), the raw material may contain ammonia (NH₃) and SiH₄.

Next, an organometallic compound raw material 53 was introduced for the formation of a gate electrode (FIG. 6C). Consequently, a cylindrical gate electrode 20 was formed coaxially over the carbon nanotube 50 with the interposition of the gate insulating layer 52 (FIG. 6D). In this process, the gate electrode 20 was formed only in a center part for the same reason as in the formation of the gate insulating layer. Such organometallic compounds are preferably metallocenes such as methylcyclopentadienyl trimethyl platinum (Pt[(C₅H₄—CH₃)(CH₃)₃]) and bismethylcyclopentadienyl nickel (Ni[C5H₄—CH₃]₂), and metal alkoxides such as niobium ethoxide ((C₂H₅O)₅Nb) and tantalum ethoxide ((C₂H₅O)₅Ta). They may also be other metal-containing compounds.

Next, a dopant 54 was added in a high concentration to both ends of the carbon nanotube 50 (FIG. 6E). Consequently, the both ends of the carbon nanotube 50 were metallized. The metallized ends acted as a source electrode 24 and a drain electrode 22 (FIG. 6F). The dopant to be added may be any of various elements, molecules, and clusters, as long as they are capable of metallizing the carbon nanotube 50. Examples of donor elements as the dopant are alkali metals, alkaline earth metals, main group metals, and lanthanoid metals. The alkali metals include cesium (Cs), rubidium (Rb), potassium (K), sodium (Na), and lithium (Li). The alkaline earth metals include barium (Ba), strontium (Sr), calcium (Ca), and magnesium (Mg). The main group metals include aluminum (Al), gallium (Ga), indium (In), and thallium (Tl). When molecules and clusters are used as a donor, they may have an ionization potential of about 6.4 eV or less. Examples of acceptor elements as the dopant are iodine (I), bromine (Br), chlorine (Cl), and fluorine (F). When molecules and clusters are used as an acceptor, they may have an electron affinity of about 2.3 eV or more,

Ultimately, a coaxial cylindrical field-effect transistor was fabricated (FIG. 6F). The transistor was measured on important indexes of performance thereof, such as the channel mobility, subthreshold level (S), and on/off ratio of the drain current. The results show that the transistor acts as a field-effect transistor, exhibits very high performance, and consumes less electric power.

A carbon nanotube is taken as an example of the nanowire above. Similar semiconductor devices can be obtained from nanowires comprising other semiconductor elements, such as Si, GaN, AlN, BN, and BCN.

### Second Embodiment

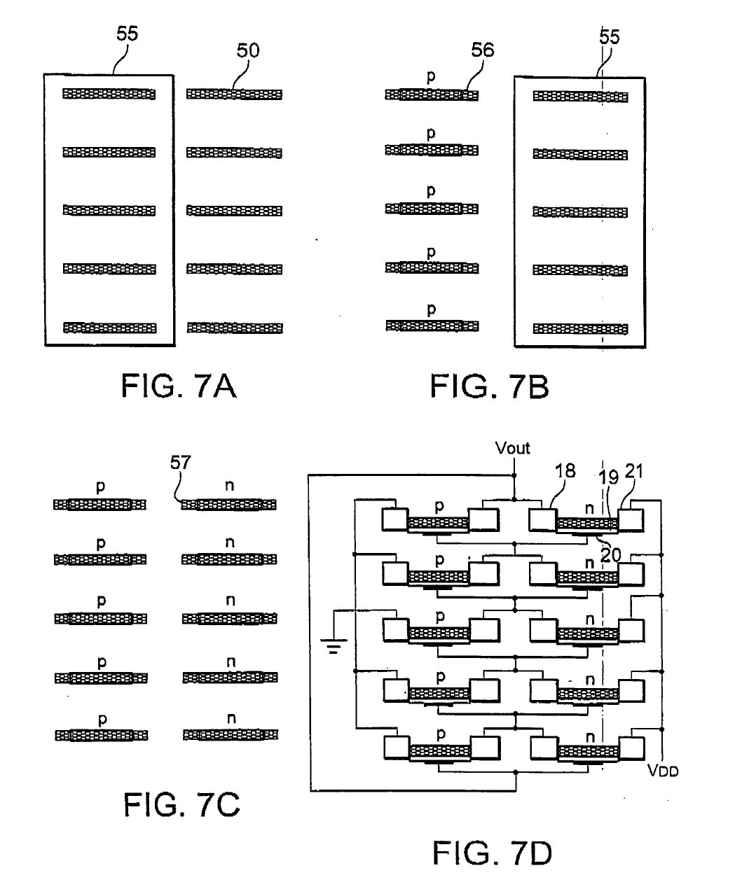

FIGS. 7A, 7B, 7C, and 7D are schematic diagrams showing the procedures of manufacturing a ring oscillation circuit according to Second Embodiment of the present invention. The ring oscillation circuit comprises inverters in combination. Each of the inverters comprises a p-type carbon nanotube field-effect transistor and an n-type carbon nanotube field-effect transistor.

In this embodiment, the external energy for processing is an electromagnetic wave resonating energy levels of the carbon nanotube. Initially, undoped intrinsic semiconductor carbon nanotubes 50 were prepared, and an electromagnetic wave was applied to regions 55 in FIG. 7A while feeding a raw material of a p-type dopant (FIG. 7A). Consequently, p-type carbon nanotubes 56 were formed (FIG. 7B). Next, an electromagnetic wave was applied to regions 55 in FIG. 7B while feeding a raw material of an n-type dopant. Consequently, n-type carbon nanotubes 57 were formed (FIG. 7C). Finally, a source-electrode leading 18, a drain-electrode leading 21, a gate insulating layer 19, a gate electrode 20, and interconnections were formed. Thus, the ring oscillation circuit was manufactured. The electrical properties of the ring oscillation circuit were evaluated to find that the ring oscillation circuit operates satisfactorily,

### Third Embodiment

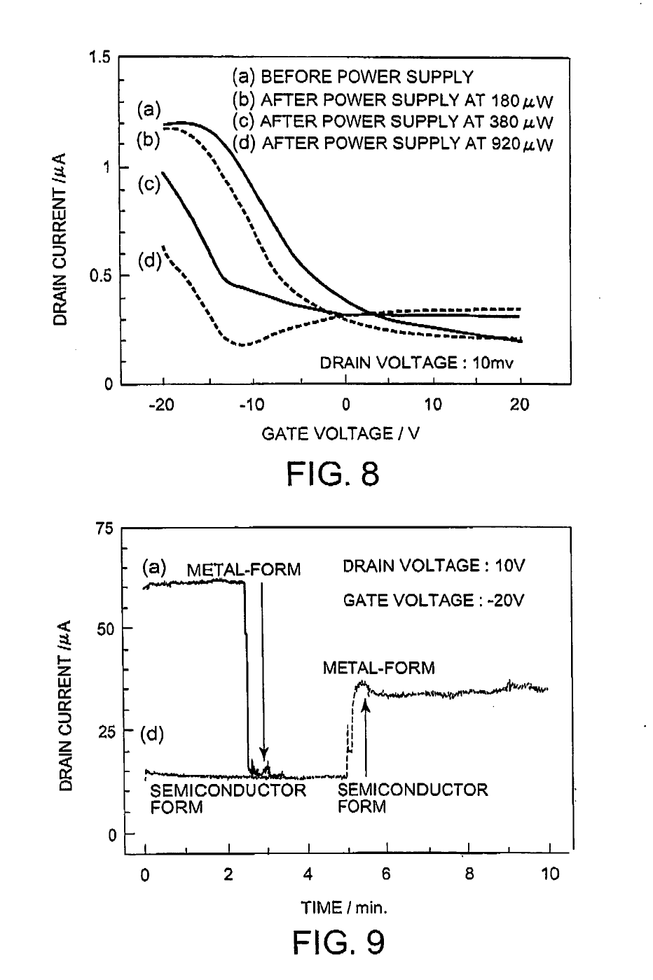

FIG. 8 shows the drain current-gate voltage characteristic of a carbon nanotube field-effect transistor. The field-effect transistor shows conduction converted from p-type conduction to ambipolar conduction by the method according to an embodiment of the present invention.

In this embodiment, electric power was applied as the external energy. The electric properties of the field-effect transistor were determined using the measuring system in FIG. 5. The drain voltage in these measurements was set at 10 mV. The characteristic curve (a) in FIG. 8 shows the drain current-gate voltage characteristic of the field-effect transistor before power supply. The characteristic curves (b), (c), and (d) show the drain current-gate voltage characteristics after electric power of 180 μW, 380 μW, and 920 μW were supplied, respectively. The characteristic curve (a) demonstrates that the carbon nanotube field-effect transistor shows p-type conduction in which the drain current increases at negative gate voltage. The drain current-gate voltage characteristic gradually shifts from the curve (b) to the curve (c) with an increasing power supply. Ultimately, the field-effect transistor shows ambipolar conduction as in the characteristic curve (d), in which the drain current increases both with an increasing negative gate voltage and with an increasing positive gate voltage. These results demonstrate that the conduction of a carbon nanotube channel may be converted from p-type conduction to ambipolar conduction. The similar advantages were obtained in field-effect transistors comprising other nanowires.

### Fourth Embodiment

FIG. 9 shows the change in drain current of a carbon nanotube field-effect transistor with time. This figure demonstrates that the carbon nanotube may be converted between a metal form and a semiconductor form using the method according to the present invention.

In Fourth Embodiment, electric power was supplied as the external energy, and the electric properties of the field-effect transistor were determined using the measuring system in FIG. 5, as in Third Embodiment. The drain voltage and the gate voltage in these measurements were set at 10 V and −20 V, respectively. The characteristic curve (a) in FIG. 9 demonstrates that the carbon nanotube channel did not vary depending on gate voltage and was identified as a metal form. The drain current suddenly fell from about 60 μA to about 15 μA about 2.5 minutes into the application of electric power to the metallic carbon nanotube channel at 10 V and 60 μA (=600 μW). The drain current-gate voltage characteristic of the carbon nanotube field-effect transistor was determined after the fall of the drain current. As a result, the field-effect transistor showed specific n-type conduction in which the drain current increases at an increasing negative gate voltage. These results demonstrate that the conduction type of the carbon nanotube is converted from a metallic conduction to an n-type semiconductor conduction.

The characteristic curve (b) shows the drain current-gate voltage characteristic of another carbon nanotube field-effect transistor. The field-effect transistor initially showed a p-type conduction. The drain current suddenly increased from about 15 μA to about 35 μA about five minutes into the power supply to the p-type semiconductor carbon nanotube channel at 10 V and 15 μA (=150 μW). After the sudden increase of the drain current, the carbon nanotube channel did not vary depending on gate voltage. These results demonstrate that the conduction type of the carbon nanotube may be converted from an n-type semiconductor conduction to a metallic conduction. These two examples clearly demonstrate that the properties of nanowires may be converted using the method according to the present invention.

Various physical mechanisms are possible as the mechanism for the conversion between a metallic carbon nanotube and a semiconductor carbon nanotube. One of possible physical mechanisms is as follows. Specifically, the applied external energy causes rearrangement of carbon-carbon bonds constituting the carbon nanotube. This in turn causes the change in helicity or radius of the carbon nanotube to thereby convert the conduction type of the carbon nanotube.

### Fifth Embodiment

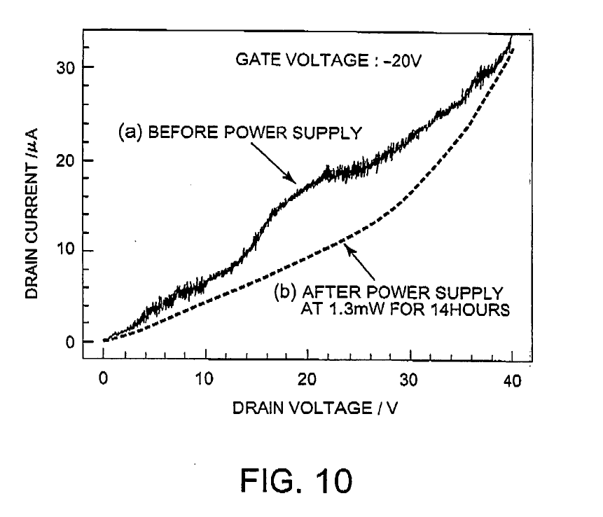

FIG. 10 shows the drain current-drain voltage characteristic of a carbon nanotube field-effect transistor. The figure demonstrates that the properties of the carbon nanotube field-effect transistor are improved.

In this embodiment, electric power was applied as the external energy. The electric properties of the field-effect transistor were determined using the measuring system in FIG. 5. The gate voltage in these measurements was set at −20 mV. The characteristic curve (a) in FIG. 10 shows the characteristic before power supply. The characteristic curve (a) demonstrates that the characteristic shows much noise and includes an irregular structure at drain voltages of about 12 V to about 24 V. The characteristic curve (b) shows the characteristic after supplying electric power of 1.3 mW for fourteen hours. In contrast to the characteristic curve (a), the characteristic curve (b) is smooth and is free from the noise and irregular structure shown in the characteristic curve (a). These results indicate that the power supply removes a structural defect in the carbon nanotube channel or it removes a charge trap in the gate insulating layer. This means the properties of the carbon nanotube field-effect transistor are significantly improved. These tendencies are also found in field-effect transistors comprising other nanowires. Accordingly, the results verify that the method according to an embodiment of the present invention serves to convert properties of a nanowire or a material arranged in the vicinity of the nanowire and to improve the performance of a nanowire field-effect transistor.

The methods according to embodiments of the present invention may enable the following micromachining and conversion of properties, in addition to examples shown in First to Fifth Embodiments.
(1) Chemical modification of a surface of a nanowire to thereby impart a function to the surface;
(2) Formation of a one-dimensional structure of a semiconductor or a metal using a nanowire as a template by supplying a suitable raw material;
(3) Crystal growth using a nanowire as a crystal seed by supplying a raw material containing the same compositional elements as the nanowire;
(4) Local coverage of a nanowire with a photo-curable or thermosetting resin or an electron beam resist;
(5) Doping by replacing a constitutional element of a nanowire with another element;
(6) Conversion of the conduction type of a nanowire, between a p-type conduction and an n-type conduction;
(7) Solution to problems in hysteresis of the drain current-gate voltage characteristic;
(8) Improvements in electric properties of a gate oxide film, and minute adjustment of the gate voltage threshold;
(9) Reduction in contact resistance between a nanowire and an electrode, and dissolution of Schottky barrier; and
(10) Activation with dopant of the vicinity of a nanowire channel.

As is described above, the present invention is applicable to electronic instruments and optical instruments including semiconductor devices such as high-performance transistors, diodes, light-emitting devices, laser oscillation elements, sensors, and logical circuits.

1. A method of manufacturing a semiconductor device, comprising the steps of:
applying external energy to a nanowire material to cause minute energy locally;
externally feeding a raw material; and
carrying out a chemical reaction or solid phase growth of the raw material using the minute energy to thereby carry out a self-aligned processing of he nanowire material or the vicinity thereof alone.

2. The method according to claim 1, further comprising using a carbon nanotube as the nanowire material.

3. The method according to claim 1, further comprising applying at least one of electric power and an electromagnetic wave as the external energy.

4. The method according to claim 3, wherein the electromagnetic wave comprises a microwave or an infrared ray.

5. The method according to claim 1, further comprising the steps of:
arranging the nanowire material at plural positions of a substrate; and
applying an electromagnetic wave as the external energy to the nanowire material to thereby heat the nanowire material alone selectively and locally, the electromagnetic wave being not absorbed by the substrate.

6. The method according to claim 1, wherein the minute energy comprises at least one of Joule heat, light, and a thermoelectron.

7. A method of manufacturing a semiconductor device, comprising the steps of:
applying external energy to a nanowire material to cause minute energy locally; and
carrying out local conversion of a property of the nanowire material or a property of a material arranged in the vicinity of the nanowire material using the minute energy.

8. The method according to claim 7, further comprising using a carbon nanotube as the nanowire material.

9. The method according to claim 7, further comprising applying electric power or an electromagnetic wave as the external energy.

10. The method according to claim 9, wherein the electromagnetic wave comprises a microwave or an infrared ray.

11. The method according to claim 7, further comprising the steps of:
arranging the nanowire material at plural positions of a substrate; and
applying an electromagnetic wave to the nanowire material to thereby heat the nanowire material alone selectively and locally, the electromagnetic wave being not absorbed by the substrate.

12. The method according to claim 7, wherein the minute energy comprises at least one of Joule heat, light, and a thermoelectron.

13. The method according to claim 12, further comprising the step of:
using a nanowire material including a defect; and
annealing the nanowire material using the Joule heat to thereby eliminate the defect from the nanowire material.

14. A semiconductor device manufactured by the method according to claim 1.

15. The semiconductor device according to claim 14, as one selected from the group consisting of transistors, diodes, light-emitting devices, laser oscillators, sensors, and logical circuits.

16. An electronic apparatus, comprising the semiconductor device according to claim 14.

17. An optical apparatus, comprising the semiconductor device according to claim 14.
